(19) United States
(12) Patent Application Publication
(10) Pub. No.: US 2025/0212462 A1
(43) Pub. Date: Jun. 26, 2025

(54) SILICON COMPATIBLE HIGH TEMPERATURE GALLIUM NITRIDE PROCESS

(71) Applicant: Analog Devices, Inc., wilmington, MA (US)

(72) Inventors: James G. Fiorenza, Carlisle, MA (US); Daniel Piedra, Somerville, MA (US)

(21) Appl. No.: 18/939,197

(22) Filed: Nov. 6, 2024

Related U.S. Application Data
(60) Provisional application No. 63/612,883, filed on Dec. 20, 2023.

(51) Int. Cl. H01L 29/47; H01L 21/285; H01L 29/20; H01L 29/423; H01L 29/66; H01L 29/778

(52) U.S. Cl. CPC H10D 30/675; H01L 21/28581; H01L 21/28587; H10D 30/015; H10D 30/475; H10D 30/6738; H10D 62/85; H10D 62/8503; H10D 64/411; H10D 64/64

(57) ABSTRACT

Described is a GaN fabrication process using titanium nitride (TiN) and tungsten (W) metallization optimized for high-temperature operation. An aluminum-free gate stack and backend process are disclosed. Ohmic contacts may be formed by a highly doped N+ GaN layer enabling low contact resistance with titanium nitride (TiN) and tungsten (W) metals. The gate metal thickness may be increased to counteract the higher resistivity of tungsten (W) compared to aluminum (Al). The resulting process uses only high melting point materials and is compatible with silicon carbide (SiC) or sapphire substrates for robust high-temperature GaN device performance.

### CLAIM OF PRIORITY

This application claims priority to U.S. Provisional Application Ser. No. 63/612,883, titled “SILICON COMPATIBLE HIGH TEMPERATURE GALLIUM NITRIDE PROCESS” to James G. Fiorenza et al., filed Dec. 20, 2023, which is incorporated by reference herein in its entirety.

### FIELD OF THE DISCLOSURE

This document pertains generally, but not by way of limitation, to semiconductor devices, and more particularly, to techniques for constructing gallium nitride devices.

### BACKGROUND

Gallium nitride (GaN) based semiconductors offer several advantages over other semiconductors as the material of choice for fabricating the next generation of transistors, or semiconductor devices, for use in both high voltage and high frequency applications. GaN based semiconductors, for example, have a wide bandgap that enable devices fabricated from these materials to have a high breakdown electric field and to be robust to a wide range of temperatures. The two-dimensional electron gas (2DEG) channels formed by GaN based heterostructures generally have high electron mobility, making devices fabricated using these structures useful in power-switching and amplification systems.

### SUMMARY OF THE DISCLOSURE

This disclosure describes a GaN fabrication process using titanium nitride (TiN) and tungsten (W) metallization optimized for high-temperature operation. An aluminum-free gate stack and backend process are disclosed. Ohmic contacts may be formed by a highly doped N+ GaN layer enabling low contact resistance with titanium nitride (TiN) and tungsten (W) metals. The gate metal thickness may be increased to counteract the higher resistivity of tungsten (W) compared to aluminum (Al). The resulting process uses only high melting point materials and is compatible with silicon carbide (SiC) or sapphire substrates for robust high-temperature GaN device performance.

In some aspects, this disclosure is directed to a compound semiconductor heterostructure transistor device comprising: a substrate including a first material; a first semiconductor material layer formed over the substrate; first and second portions of a second semiconductor material layer formed over the first semiconductor material layer; a third semiconductor material layer formed over the first semiconductor material layer and between the first and second portions of the second semiconductor material layer so as to form a compound semiconductor heterostructure having a two-dimensional electron gas (2DEG) channel; a drain electrode electrically coupled with the 2DEG channel via the first portion of the second semiconductor material layer, wherein the drain electrode includes a second material having a melting point above 500 degrees Celsius; a source electrode electrically coupled with the 2DEG channel via the second portion of the second semiconductor material layer, wherein the source electrode includes a third material having a melting point above 500 degrees Celsius; and a gate electrode formed over the third semiconductor material layer, wherein the gate electrode includes a fourth material having a melting point above 500 degrees Celsius.

In some aspects, this disclosure is directed to a method of forming a compound semiconductor heterostructure transistor device, the method comprising: forming a first semiconductor material layer over a substrate, wherein the substrate includes a first material; forming first and second portions of a second semiconductor material layer over the first semiconductor material layer; forming a third semiconductor material layer over the first semiconductor material layer and between the first and second portions of the second semiconductor material layer so as to form a compound semiconductor heterostructure having a two-dimensional electron gas (2DEG) channel; forming a drain electrode including a second material having a melting point above 500 degrees Celsius, and electrically coupling the drain electrode with the 2DEG channel via the first portion of the second semiconductor material layer; forming a source electrode including a third material having a melting point above 500 degrees Celsius, and electrically coupling the source electrode with the 2DEG channel via the second portion of the second semiconductor material layer; and forming a gate electrode over the third semiconductor material layer, wherein the gate electrode includes a fourth material having a melting point above 500 degrees Celsius.

In some aspects, this disclosure is directed to a method of forming a compound semiconductor heterostructure transistor device, the method comprising: forming a first semiconductor material layer over a substrate, wherein the substrate includes a first material; forming first and second portions of a second semiconductor material layer over the first semiconductor material layer; forming a third semiconductor material layer over the first semiconductor material layer and between the first and second portions of the second semiconductor material layer so as to form a compound semiconductor heterostructure having a two-dimensional electron gas (2DEG) channel; forming a drain electrode including a second material having a melting point above 500 degrees Celsius, and electrically coupling the drain electrode with the 2DEG channel via the first portion of the second semiconductor material layer; forming a source electrode including a third material having a melting point above 500 degrees Celsius, and electrically coupling the source electrode with the 2DEG channel via the second portion of the second semiconductor material layer; forming a gate electrode over the third semiconductor material layer, wherein the gate electrode includes a fourth material having a melting point above 500 degrees Celsius; forming a Schottky barrier material including titanium nitride in contact with the third semiconductor material layer; and annealing the Schottky barrier material at a temperature in the range of 400° C. to 500° C. to crystallize the titanium nitride.

### BRIEF DESCRIPTION OF THE DRAWINGS

In the drawings, which are not necessarily drawn to scale, like numerals may describe similar components in different views. The drawings illustrate generally, by way of example, but not by way of limitation, various embodiments discussed in the present document.

FIG. 1 depicts a cross-sectional diagram of an example of a compound semiconductor heterostructure transistor device.

FIG. 2 depicts a cross-sectional diagram of an example of a compound semiconductor heterostructure transistor device that may implement various techniques of this disclosure.

FIG. 3 depicts an enlarged view of a portion of the cross-sectional diagram of FIG. 2.

FIG. 4 depicts a cross-sectional diagram of another example of a compound semiconductor heterostructure transistor device that may implement various techniques of this disclosure.

FIGS. 5A and 5B depict a flow diagram of an example of a process flow for forming a compound semiconductor heterostructure transistor device.

FIG. 5B illustrates an aspect of the subject matter in accordance with one embodiment.

FIG. 6 is a flow diagram of an example of a method of forming a compound semiconductor heterostructure transistor device.

FIG. 7 is a flow diagram of another example of a method of forming a compound semiconductor heterostructure transistor device.

### DETAILED DESCRIPTION

As used in this disclosure, a GaN-based compound semiconductor material may include a chemical compound of elements including GaN and one or more elements from different groups in the periodic table. Such chemical compounds may include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table may also be referred to as Group III and group 15 as Group V. In an example, a semiconductor device may be fabricated from GaN and aluminum indium gallium nitride (AlInGaN).

Heterostructures described herein may be formed as AlN/GaN/AlN hetero-structures, InAlN/GaN heterostructures, AlGaN/GaN heterostructures, or heterostructures formed from other combinations of group 13 and group 15 elements. These heterostructures may form a two-dimensional electron gas (2DEG) at the interface of the compound semiconductors that form the heterostructure, such as the interface of GaN and AlGaN. The 2DEG may form a conductive channel of electrons that may be controllably depleted, such as by an electric field formed by a buried layer of p-type material disposed below the channel. The conductive channel of electrons may also be controllably enhanced, such as by an electric field formed by a gate terminal disposed above the channel to control a current through the semiconductor device. Semiconductor devices formed using such conductive channels may include high electron mobility transistor (HEMT) devices.

GaN semiconductor devices have gained significant interest for high frequency, high power applications due to the high breakdown voltage and high electron mobility of GaN. GaN high electron mobility transistors (HEMTs) built on silicon carbide (SiC) or sapphire substrates have shown excellent high-frequency performance.

The present inventors have recognized that a major challenge for GaN devices is operating at high temperatures, such as temperatures above 500° C. The typical metallization used in GaN fabrication includes aluminum (Al), which has a relatively low melting point of 660° C., limiting high-temperature operation. The present inventors have recognized that replacing Al with metals like tungsten (W) or titanium nitride (TiN), which have melting points around or above 3000° C., may enable high-temperature capability. The higher resistivity of these metals may be compensated by increasing metal thicknesses to maintain low resistances required for radio frequency (“RF”) performance.

This disclosure describes a GaN fabrication process using titanium nitride (TiN) and tungsten (W) metallization optimized for high-temperature operation. An aluminum-free gate stack and backend process are disclosed. Ohmic contacts may be formed by a highly doped N+ GaN layer enabling low contact resistance with titanium nitride (TiN) and tungsten (W) metals. The gate metal thickness may be increased to counteract the higher resistivity of tungsten (W) compared to aluminum (Al). The resulting process uses only high melting point materials and is compatible with silicon carbide (SiC) or sapphire substrates for robust high-temperature GaN device performance.

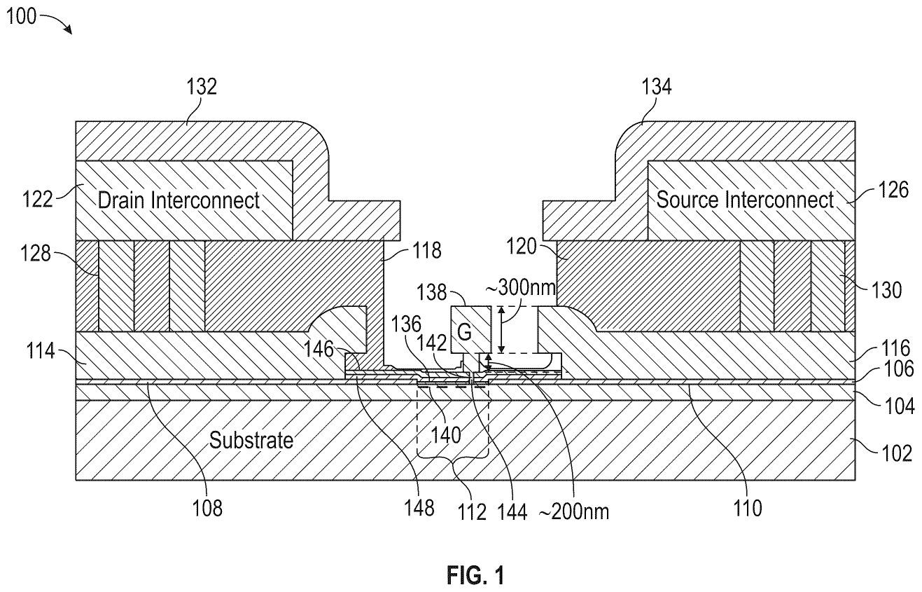

FIG. 1 depicts a cross-sectional diagram of an example of a transistor device. The compound semiconductor heterostructure transistor device 100 shown in FIG. 1 includes a substrate 102. A layer of semiconductor material 104 such as gallium nitride (GaN) is formed over the substrate 102 to form the channel layer.

Next, a layer of semiconductor material 106, e.g., highly doped N+ GaN, such as with a doping of about 1e20 cm⁻³ to about 3e20 cm⁻³, is formed over the GaN layer 104. The highly doped N+ GaN allows low contact resistance while being relatively agnostic to the metal type, thickness, recess depth, or anneal temperature. Note that the N+ GaN layer 106 does not extend completely across the transistor device. Rather, the N+ GaN layer 106 includes a first portion 108 and second portion 110 separated by a gap 112, where the gap 112 is in the layer of N+ GaN under and adjacent to the T-gate electrode (G) 138. The T-gate design is used in high-frequency transistors like field-effect transistors (FETs), especially in radio frequency (RF) and microwave applications. In these designs, the gate electrode has a cross-sectional shape that resembles the letter “T,” where the top portion provides a wider surface area to reduce gate resistance, while the vertical part of the “T” controls the channel. The T-gate structure is beneficial for achieving higher switching speeds and reducing parasitic capacitance, which improves overall transistor performance at high frequencies. The geometry helps enhance both the device's efficiency and its performance in advanced electronic applications like RF communication, radar systems, and high-speed integrated circuits.

A layer of semiconductor material 136, e.g., aluminum gallium nitride (AlGaN), is formed over the layer of semiconductor material 104 and between the first portion 108 and the second portion 110 of the layer of semiconductor material 106, e.g., highly doped N+ GaN, so as to form a compound semiconductor heterostructure having a two-dimensional electron gas (2DEG) channel 140. The 2DEG channel 140 is more conductive than the layer of semiconductor material 104, e.g., GaN, or the layer of semiconductor material 136, e.g., AlGaN.

The gate electrode 138, e.g., aluminum, is formed over the layer of semiconductor material 136. The gate electrode 138 is coupled with the layer of semiconductor material 136 by a connector 142 and a plug 144, where the connector 142 extends between the gate electrode 138 and the plug 144. The connector 142 includes tungsten, for example, and the plug 144 includes a Schottky barrier material, such as titanium nitride (TiN). The connector 142 extends through two layers of silicon nitride (SiN), namely silicon nitride layer 146 and silicon nitride layer 148.

In the example shown, the gate electrode 138 has a height of about 300 nanometers (nm). The connector 142 has a height of about 200 nm.

A first layer of aluminum is formed over the first portion 108 of the highly doped N+ GaN to form a drain contact metal 114. Similarly, a first layer of aluminum is formed over the second portion 110 of the highly doped N+ GaN to form a source contact metal 116. The drain contact metal 114 is electrically coupled with the 2DEG channel 140 via the first portion 108 of the layer of semiconductor material 106 and the source contact metal 116 is electrically coupled with the 2DEG channel 140 via the second portion 110 of the layer of semiconductor material 106.

A layer of silicon dioxide 118 (SiO₂), which has a high-temperature melting point around 1600° C., is formed over drain contact metal 114. Similarly, a layer of silicon dioxide 120 is formed over the source contact metal 116.

A second layer of aluminum is formed over the layer of silicon dioxide 118 to form a drain interconnect 122 that functions as a drain electrode. Similarly, a second layer of aluminum is formed over the layer of silicon dioxide 120 to form a source interconnect 126 that functions as a source electrode. The drain interconnect 122 is electrically connected to the drain contact metal 114 using one or more vias 128, e.g., tungsten, and the source interconnect 126 is electrically connected to the source contact metal 116 using one or more vias 130, e.g., tungsten.

A layer of silicon nitride 132 (SiN), with a high-temperature melting point around 1900° C., is formed over the drain interconnect 122 and a layer of silicon nitride 134 is formed over the source interconnect 126.

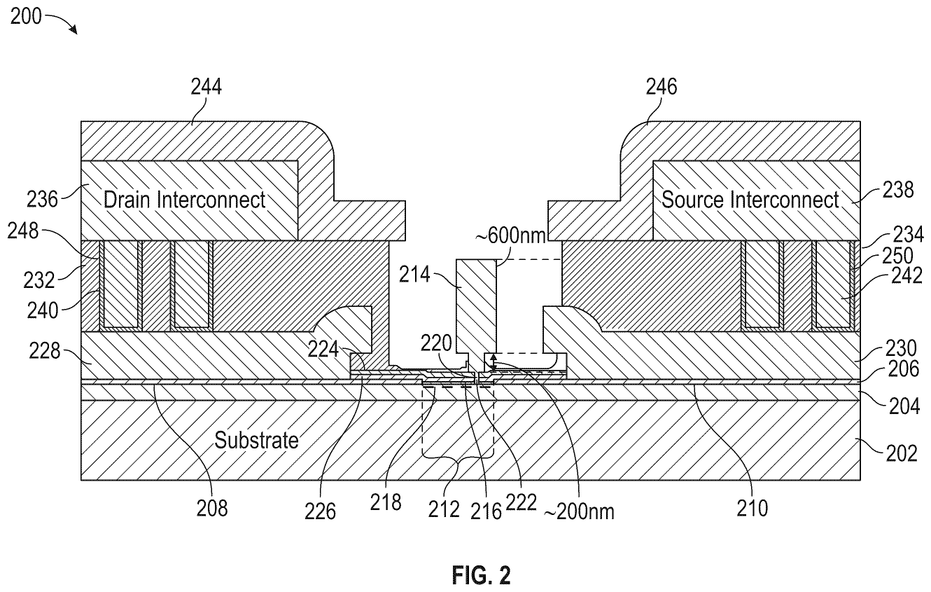

FIG. 2 depicts a cross-sectional diagram of an example of a transistor device that may implement various techniques of this disclosure. In FIG. 2, the low-temperature melting point materials, including aluminum, are replaced with high-temperature melting point materials.

The compound semiconductor heterostructure transistor device 200 shown in FIG. 2 includes a substrate 202. A layer of semiconductor material 204 such as gallium nitride (GaN) is formed over the substrate 202 to form the channel layer.

Next, a layer of semiconductor material 206, e.g., highly doped N+ GaN, is formed over the GaN layer 204. The highly doped N+ GaN allows low contact resistance while being relatively agnostic to the metal type, thickness, recess depth, or anneal temperature. Note that the N+ GaN layer 206 does not extend completely across the transistor device. Rather, the N+ GaN layer 206 includes a first portion 208 and a second portion 210 separated by a gap 112, where the gap 212 is in the layer of N+ GaN under and adjacent to the T-gate electrode (G) 214.

A layer of semiconductor material 216, e.g., aluminum gallium nitride (AlGaN), is formed over the layer of semiconductor material 204 and between the first portion 208 and the second portion second portion 210 of the layer of semiconductor material 206, e.g., highly doped N+ GaN, so as to form a compound semiconductor heterostructure having a two-dimensional electron gas (2DEG) channel 218. The 2DEG channel 218 is more conductive than the layer of semiconductor material 206, e.g., GaN, or the layer of semiconductor material 216, e.g., AlGaN.

The gate electrode 214 is formed over the layer of semiconductor material 216. Rather than use aluminum, as in FIG. 1, the gate electrode 214 includes a material having a melting point above 500 degrees Celsius, such as tungsten (W) or molybdenum (Mo).

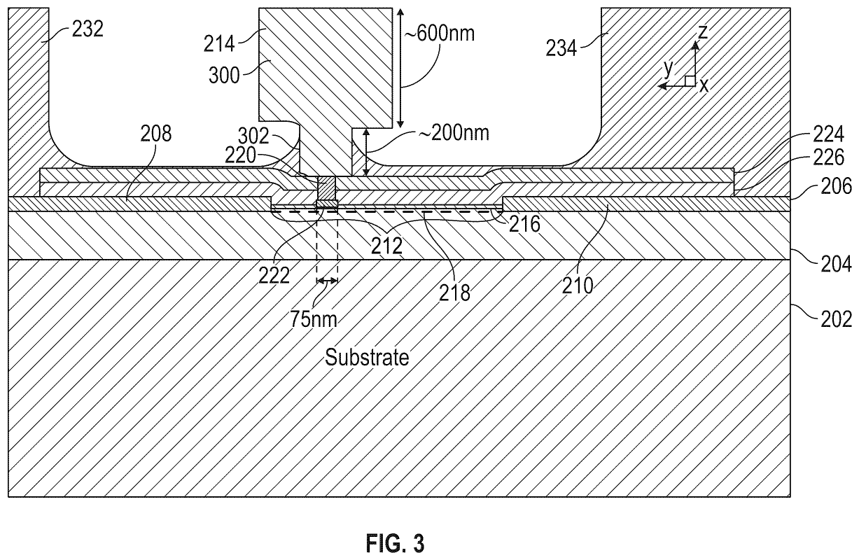

The gate electrode 214 is coupled with the layer of semiconductor material 216, e.g., AlGaN, by a connector 220 and a plug 222, where the connector 220 extends between the gate electrode 214 and the plug 222. The connector 220 includes a material having a melting point above 500 degrees Celsius, such as tungsten (W) or molybdenum (Mo). The plug 222 includes a Schottky barrier material having a melting point above 500 degrees Celsius, such as titanium nitride (TiN). The connector 220 extends through two layers of silicon nitride (SiN), namely silicon nitride layer 224 and silicon nitride layer 226. The gate and its surrounding structure are shown in more detail in FIG. 3.

A first layer of a material having a melting point above 500 degrees Celsius, such as tungsten (W) or molybdenum (Mo), is formed over the first portion 208 of the highly doped N+ GaN to form a drain contact metal 228. Similarly, a first layer of a material having a melting point above 500 degrees Celsius, such as tungsten (W) or molybdenum (Mo), is formed over the second portion 210 of the highly doped N+ GaN to form a source contact metal 230. The drain contact metal 228 is electrically coupled with the 2DEG channel 218 via the first portion 208 of the layer of semiconductor material 206 (highly doped N+ GaN) and the source contact metal 230 is electrically coupled with the 2DEG channel 218 via the second portion 210 of the layer of semiconductor material 206 (highly doped N+ GaN).

A layer of silicon dioxide 232 (SiO₂), which has a high-temperature melting point around 1600° C., is formed over drain contact metal 228. Similarly, a layer of silicon dioxide 234 is formed over the source contact metal 230.

A second layer of a material having a melting point above 500 degrees Celsius, such as tungsten (W) or molybdenum (Mo), is formed over the layer of silicon dioxide 232 to form a drain interconnect 236 that functions as a drain electrode. Similarly, a second layer of a material having a melting point above 500 degrees Celsius, such as tungsten (W) or molybdenum (Mo), is formed over the layer of silicon dioxide 234 to form a source interconnect 238 that functions as a source electrode. The drain interconnect 236 is electrically connected to the drain contact metal 228 using one or more vias 240, e.g., tungsten, and the source interconnect 238 is electrically connected to the source contact metal 230 using one or more vias 242, e.g., tungsten. In some examples, the vias 240 and the vias 242 may include a via liner 248 and a via liner 250, respectively, such as titanium nitride (TiN). The vias in FIG. 1 may include liners.

A layer of silicon nitride 244 (SiN), with a high-temperature melting point around 1900° C., is formed over the drain interconnect 236 and a layer of silicon nitride 246 is formed over the source interconnect 238.

In contrast to FIG. 1, the compound semiconductor heterostructure transistor device 200 of FIG. 2 uses gate, drain, and source materials with melting points above 500 degrees Celsius, such as tungsten (W) or molybdenum (Mo), which are significantly higher than the melting point of aluminum, which is about 660 degrees Celsius.

By utilizing high melting point materials like tungsten for the gate, drain, and source electrodes instead of conventional aluminum, the compound semiconductor heterostructure transistor device 200 of FIG. 2 may function reliably in environments with temperatures well above the melting point of aluminum. The combination of tungsten electrodes, for example, and the N+ GaN layer enables a fully high-temperature compatible process.

To compensate for tungsten's higher resistivity compared to aluminum, the gate structure of FIG. 2, e.g., the depth of the gate electrode 214, is made thicker than the gate structure of FIG. 1. This increased thickness helps maintain a low gate resistance, which is important for high-frequency performance.

The design achieves high-temperature and high-frequency capabilities using processes compatible with silicon fabrication facilities, which is uncommon for such extreme environment devices. In addition, the T-gate structure with removed dielectric around the gate electrode minimizes parasitic capacitances, further enhancing high-frequency performance.

This combination of features allows for the creation of GaN HEMT transistors capable of operating in extreme temperature environments while maintaining the high-frequency performance necessary for advanced applications.

FIG. 3 depicts an enlarged view of a portion of the cross-sectional diagram of FIG. 2. As mentioned above with respect to FIG. 2, the highly doped N+ GaN layer 206 does not extend completely across. There is a gap 212 in the layer of N+ GaN 206 under the gate electrode 214. As seen in FIG. 3, a layer of aluminum gallium nitride (AlGaN) 216 is formed under the gate region and within the gap 212 such that the layer of aluminum gallium nitride (AlGaN) 216 electrically couples the first portion 208 and the second portion 210 of the N+ GaN layer 206. The AlGaN layer 216 and the GaN layer 204 below form a heterostructure with a 2DEG channel 218 formed at their interface.

As seen in FIG. 3, a hole is etched through the silicon nitride layer 224 and the silicon nitride layer 226 under the gate electrode 214. Then, a small portion of a Schottky barrier material, e.g., titanium nitride, is deposited at the bottom of the hole and in contact with the AlGaN layer to form a plug 222. Then, a material such as tungsten or molybdenum is used to fill the hole and form the connector 220. The gate electrode 214 is in electrical contact with the layer of semiconductor material 216, e.g., AlGaN, by way of the connector 220 and the plug 222.

As mentioned above, the gate electrode 214 is a T-gate. The gate electrode 214 includes a cap 300 and a stem 302. The cap 300 is the wide, horizontal part of the “T” at the top of the gate electrode 214 and the stem 302 is the narrow, vertical part of the “T” that connects the cap 300 to the connector 220. In the example shown, the cap 300 has a depth of about 600 nm and the stem 302 has a depth of about 200 nm. The connector 220 and the plug 222 have a width of about 75 nm.

By using these techniques, aluminum and other low-temperature melting point materials are replaced with high-temperature melting point materials such as titanium nitride (TiN) and tungsten (W), with the exception of the GaN. However, aluminum has a resistivity of about 2.7 μOhm-cm, but tungsten has a resistivity of about 5.6 μOhm-cm, and titanium nitride has a resistivity of about 30 μOhm-cm. Because the resistivity of tungsten is about twice that of aluminum, to maintain the same resistance, the thickness of tungsten in FIG. 2 should be about twice that of the aluminum in FIG. 1. For example, the tungsten T-shaped gate electrode in FIG. 2 is about twice as thick as the aluminum T-shaped gate electrode in FIG. 1. In addition, the tungsten drain and source electrodes in FIG. 2 are about twice as thick as the aluminum drain and source electrodes in FIG. 1.

In some examples, such as shown in FIGS. 2-4, only the Schottky barrier material and the via liners include titanium nitride (TiN). That is, there is no other TiN in the compound semiconductor heterostructure transistor device other than the TiN of the Schottky barrier material and the via liners. The present inventors have recognized that TiN, when annealed at high temperatures, crystallizes and forms a stable structure that prevents diffusion, unlike other materials such as nickel, which tend to diffuse and degrade at high temperatures. The annealing process transforms the TiN from a polycrystalline or amorphous state into a crystalline state.

This crystallization is important because a crystalline TiN structure has a higher melting point and better stability, making it suitable for high-temperature applications. This crystallization ensures that the TiN remains intact and does not diffuse into other layers, thereby maintaining the integrity and performance of the device at high temperatures. This property is particularly beneficial for the Schottky barrier, which plays an important role in the device's operation by forming a stable and reliable barrier at high temperatures.

In some examples, the TiN is annealed at a temperature range of 400 degrees Celsius to 500 degrees Celsius. At these temperatures, TiN crystallizes effectively without causing adverse effects on the other materials in the device.

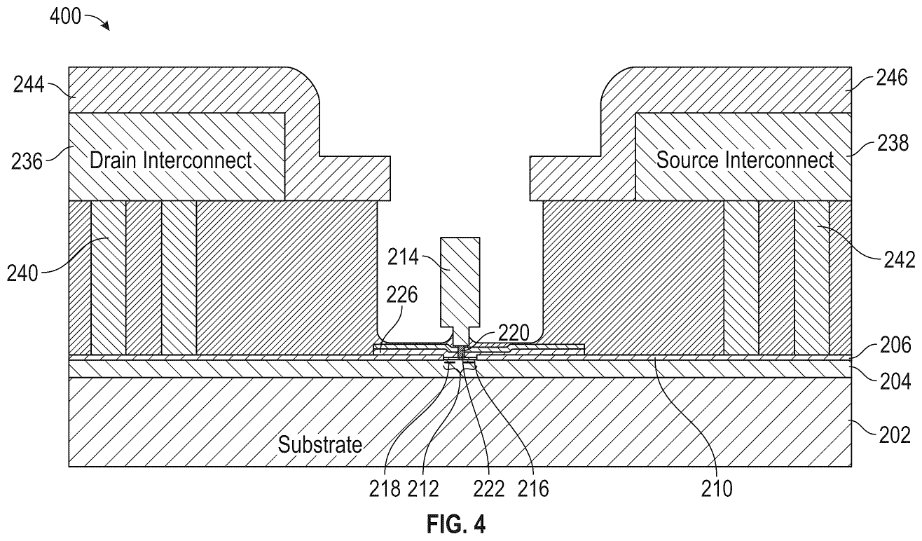

FIG. 4 depicts a cross-sectional diagram of another example of a compound semiconductor heterostructure transistor device 400 that may implement various techniques of this disclosure. The transistor device in FIG. 4 is similar to the transistor device in FIG. 2 except that the compound semiconductor heterostructure transistor device 400 eliminates the intermediate layers of the drain contact metal 228 and the source contact metal 230 between the top interconnect metal layers of the drain interconnect 236 and the source interconnect 238 and the N+ GaN layer 206. Instead, tungsten or molybdenum vias make direct contact with the N+ GaN layer 206.

By removing these intermediate metal layers, the compound semiconductor heterostructure transistor device 400 of FIG. 4 may simplify the manufacturing process, such as by reducing the number of lithography steps used, because there is no need to pattern an additional metal layer. The simplified structure also eliminates a metal deposition step, which may lead to reduced production time and potentially lower manufacturing costs.

The direct contact between the vias and the N+ GaN layer 206 maintains the high-temperature compatibility of the device, because both materials have high melting points suitable for extreme temperature environments. The simplified structure may also reduce the overall thickness of the device, which may be advantageous in certain applications where device dimensions are important.

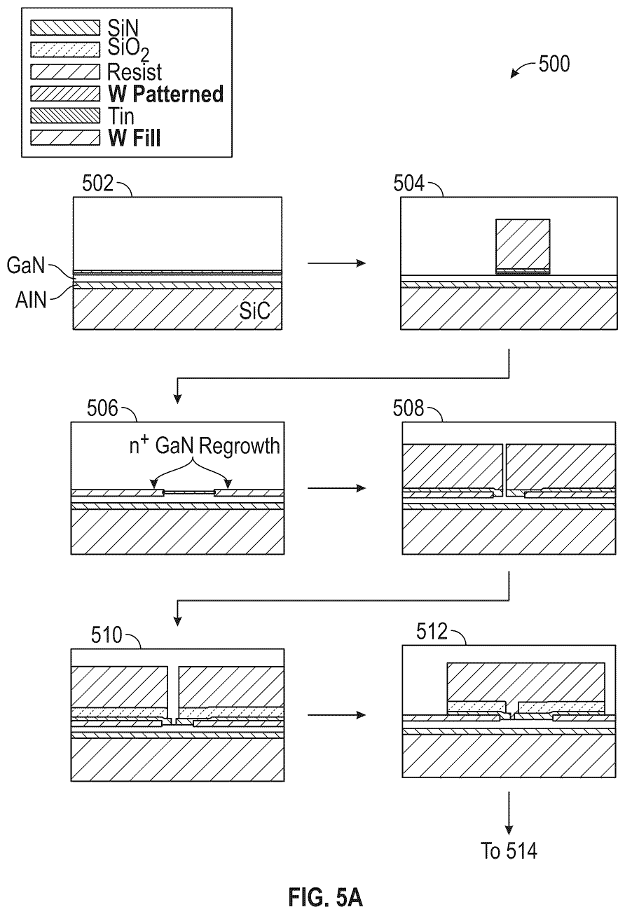

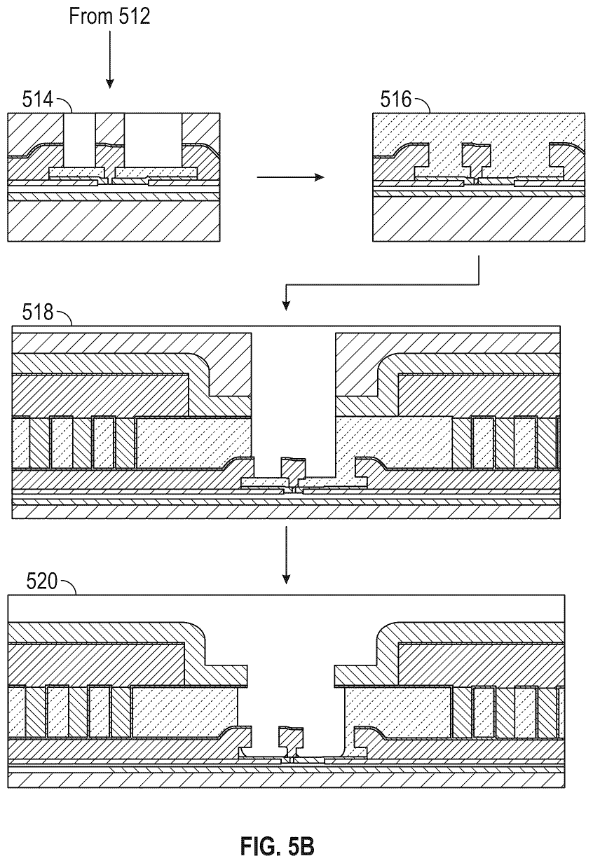

FIGS. 5A and 5B depict a flow diagram of an example of a process flow 500 for forming a compound semiconductor heterostructure transistor device. The process flow 500 may be used to form the compound semiconductor heterostructure transistor device 200 of FIG. 2, for example. Similar steps may be used to form the compound semiconductor heterostructure transistor device 400 of FIG. 4.

At block 502, a silicon nitride (SiN) passivation layer is deposited on the starting wafer, which includes a substrate (e.g., silicon carbide or sapphire), an aluminum nitride (AlN) nucleation layer, a gallium nitride (GaN) channel, and an aluminum gallium nitride (AlGaN) barrier.

At block 504, ohmic contact openings in the SiN and AlGaN are patterned and etched.

At block 506, a highly doped n+ GaN layer is grown in the ohmic contact openings.

At block 508, a SiN layer is deposited and a gate opening is patterned and etched.

At block 510, a silicon dioxide (SiO₂) layer is deposited, an opening is patterned and etched in the SiO2, and the gate opening is plugged with tungsten, molybdenum, or another suitable metal with a melting point above 500 degrees Celsius. In addition, a Schottky barrier layer, such a TiN, may be deposited beneath the tungsten.

At block 512, openings are patterned and etched in the SiO₂ layer to expose the highly doped n+ GaN.

At block 514, tungsten, molybdenum, or another suitable metal with a melting point above 500 degrees Celsius is deposited and patterned. This single-layer metal is used for both the gate head and the contact metals on the source and drain.

At block 516, SiO₂ is deposited.

At block 518, vias are etched in the SiO₂ and filled with tungsten, for example. The tungsten is deposited and patterned to be the top metal to contact the source and drain, SiN is deposited, and an opening is patterned around the gate and dry etched to expose the gate.

At block 520, the SiO₂ under the gate head is isotropically etched using a vapor hydrofluoric acid.

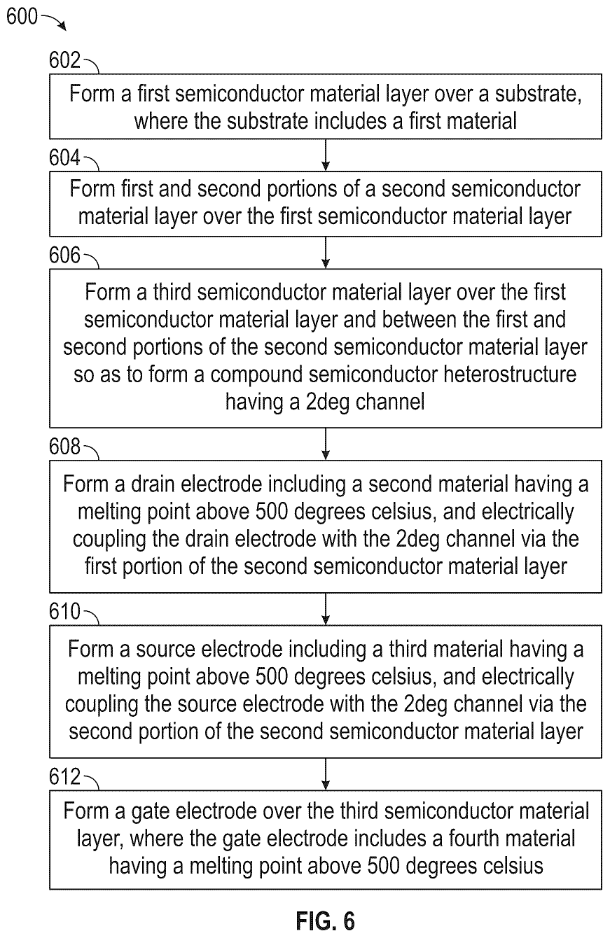

FIG. 6 is a flow diagram of an example of a method 600 of forming a compound semiconductor heterostructure transistor device. The method 600 may be used to make the compound semiconductor heterostructure transistor device 200 and compound semiconductor heterostructure transistor device 400 of FIGS. 2-4. At block 602, the method 600 includes forming a first semiconductor material layer over a substrate, where the substrate includes a first material. For example, a layer of GaN is formed over a substrate of silicon carbide or sapphire.

At block 604, the method 600 includes forming first and second portions of a second semiconductor material layer over the first semiconductor material layer. For example, portions of highly doped N+ GaN are formed over the GaN layer 204 in FIG. 2, with a gap 212 left between the portions.

At block 606, the method 600 includes forming a third semiconductor material layer over the first semiconductor material layer and between the first and second portions of the second semiconductor material layer so as to form a compound semiconductor heterostructure having a two-dimensional electron gas (2DEG) channel. For example, a layer of AlGaN 216 is formed over the GaN layer 204 in FIG. 2.

At block 608, the method 600 includes forming a drain electrode of a second material having a melting point above 500 degrees Celsius, and electrically coupling the drain electrode with the 2DEG channel via the first portion of the second semiconductor material layer. For example, the drain interconnect 236 is formed, such as including tungsten or molybdenum, and then electrically coupled to the 2DEG channel 218 by the via 240, drain contact metal 228, and the highly doped GaN layer 206, as shown in FIG. 2.

At block 610, the method 600 includes forming a source electrode of a third material having a melting point above 500 degrees Celsius, and electrically coupling the source electrode with the 2DEG channel via the second portion of the second semiconductor material layer. For example, the source interconnect 238 is formed, such as including tungsten or molybdenum, and then electrically coupled to the 2DEG channel 218 by the via 242, source contact metal 230, and the highly doped GaN layer 206, as shown in FIG. 2.

At block 612, the method 600 includes forming a gate electrode over the third semiconductor material layer, where the gate electrode includes a fourth material having a melting point above 500 degrees Celsius. For example, a gate electrode of tungsten or molybdenum is formed over the AlGaN layer 216 in FIG. 2. In some examples, forming the gate electrode includes forming a T-gate.

In some examples, the method 600 includes electrically coupling the gate electrode with the third semiconductor material layer via a Schottky barrier material that is different from the fourth material.

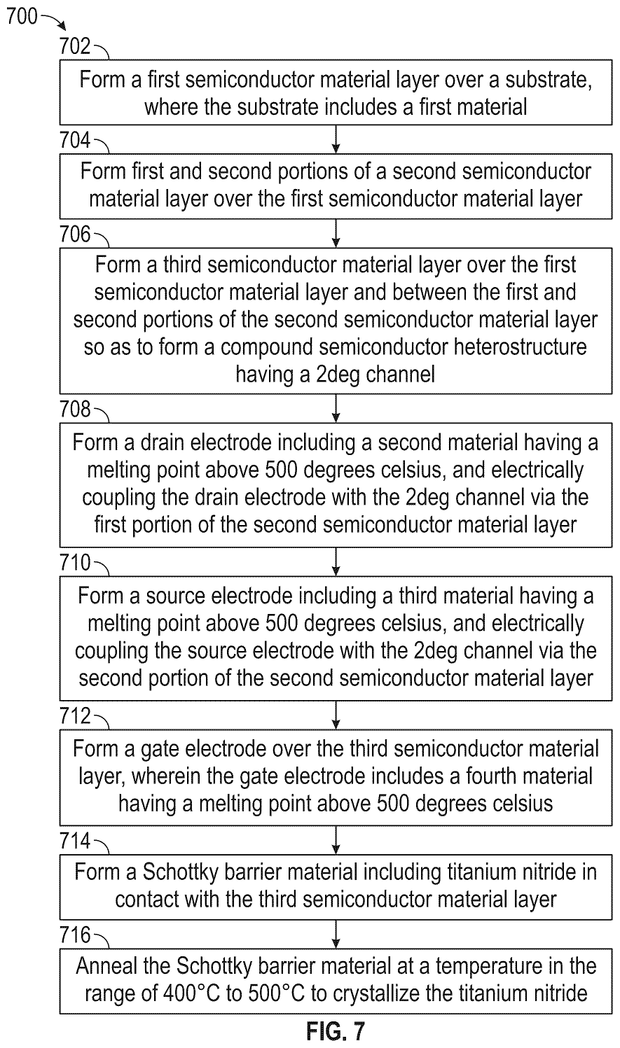

FIG. 7 is a flow diagram of another example of a method 700 of forming a compound semiconductor heterostructure transistor device. The method 700 may be used to make the compound semiconductor heterostructure transistor device 200 and compound semiconductor heterostructure transistor device 400 of FIGS. 2-4.

At block 702, the method 700 includes forming a first semiconductor material layer over a substrate, where the substrate includes a first material. For example, a layer of GaN is formed over a substrate of silicon carbide or sapphire.

At block 704, the method 700 includes forming first and second portions of a second semiconductor material layer over the first semiconductor material layer. For example, portions of highly doped N+ GaN are formed over the GaN layer 204 in FIG. 2, with a gap 212 left between the portions.

At block 706, the method 700 includes forming a third semiconductor material layer over the first semiconductor material layer and between the first and second portions of the second semiconductor material layer so as to form a compound semiconductor heterostructure having a two-dimensional electron gas (2DEG) channel. For example, a layer of AlGaN 216 is formed over the GaN layer 204 in FIG. 2.

At block 708, the method 700 includes forming a drain electrode of a second material having a melting point above 500 degrees Celsius, and electrically coupling the drain electrode with the 2DEG channel via the first portion of the second semiconductor material layer. For example, the drain interconnect 236 is formed, such as including tungsten or molybdenum, and then electrically coupled to the 2DEG channel 218 by the via 240, drain contact metal 228, and the highly doped GaN layer 206, as shown in FIG. 2.

At block 710, the method 700 includes forming a source electrode of a third material having a melting point above 500 degrees Celsius, and electrically coupling the source electrode with the 2DEG channel via the second portion of the second semiconductor material layer. For example, the source interconnect 238 is formed, such as including tungsten or molybdenum, and then electrically coupled to the 2DEG channel 218 by the via 242, source contact metal 230, and the highly doped GaN layer 206, as shown in FIG. 2.

At block 712, the method 700 includes forming a gate electrode over the third semiconductor material layer, where the gate electrode includes a fourth material having a melting point above 500 degrees Celsius. For example, a gate electrode of tungsten or molybdenum is formed over the AlGaN layer 216 in FIG. 2. In some examples, forming the gate electrode includes forming a T-gate.

At block 714, the method 700 includes forming a Schottky barrier material including titanium nitride in contact with the third semiconductor material layer. For example, a plug 222 of TiN is formed in FIG. 3 as a Schottky barrier material.

At block 716, the method 700 includes annealing the Schottky barrier material at a temperature in the range of 400° C. to 500° C. to crystallize the titanium nitride. As an example, a rapid thermal anneal (RTA) may be used, where the temperature is increased from room temperature to about 500° C. within a few seconds.

### VARIOUS NOTES

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A compound semiconductor heterostructure transistor device comprising:
a substrate including a first material;
a first semiconductor material layer formed over the substrate;
first and second portions of a second semiconductor material layer formed over the first semiconductor material layer;
a third semiconductor material layer formed over the first semiconductor material layer and between the first and second portions of the second semiconductor material layer so as to form a compound semiconductor heterostructure having a two-dimensional electron gas (2DEG) channel;
a drain electrode electrically coupled with the 2DEG channel via the first portion of the second semiconductor material layer, wherein the drain electrode includes a second material having a melting point above 500 degrees Celsius;
a source electrode electrically coupled with the 2DEG channel via the second portion of the second semiconductor material layer, wherein the source electrode includes a third material having a melting point above 500 degrees Celsius; and
a gate electrode formed over the third semiconductor material layer, wherein the gate electrode includes a fourth material having a melting point above 500 degrees Celsius.

2. The compound semiconductor heterostructure transistor device of claim 1, wherein the fourth material includes tungsten.

3. The compound semiconductor heterostructure transistor device of claim 2, wherein the second material and the third material include tungsten.

4. The compound semiconductor heterostructure transistor device of claim 1, wherein the gate electrode is a T-gate.

5. The compound semiconductor heterostructure transistor device of claim 1, wherein the gate electrode is coupled with the third semiconductor material layer via a Schottky barrier material that is different from the fourth material.

6. The compound semiconductor heterostructure transistor device of claim 5, wherein the Schottky barrier material includes titanium nitride.

7. The compound semiconductor heterostructure transistor device of claim 1, wherein only the Schottky barrier material and one or more via liners include titanium nitride.

8. The compound semiconductor heterostructure transistor device of claim 5, wherein the gate electrode is coupled with the Schottky barrier material via a connector that includes a fifth material having a melting point above 500 degrees Celsius.

9. The compound semiconductor heterostructure transistor device of claim 1, comprising:
first and second portions of metal formed over the first and second portions of the second semiconductor material layer, respectively, wherein the first and second portions of the metal are coupled with the drain electrode and the source electrode, respectively, using vias of a sixth material having a melting point above 500 degrees Celsius.

10. A method of forming a compound semiconductor heterostructure transistor device, the method comprising:
forming a first semiconductor material layer over a substrate, wherein the substrate includes a first material;
forming first and second portions of a second semiconductor material layer over the first semiconductor material layer;
forming a third semiconductor material layer over the first semiconductor material layer and between the first and second portions of the second semiconductor material layer so as to form a compound semiconductor heterostructure having a two-dimensional electron gas (2DEG) channel;
forming a drain electrode including a second material having a melting point above 500 degrees Celsius, and electrically coupling the drain electrode with the 2DEG channel via the first portion of the second semiconductor material layer;
forming a source electrode including a third material having a melting point above 500 degrees Celsius, and electrically coupling the source electrode with the 2DEG channel via the second portion of the second semiconductor material layer; and
forming a gate electrode over the third semiconductor material layer, wherein the gate electrode includes a fourth material having a melting point above 500 degrees Celsius.

11. The method of claim 10, wherein forming the gate electrode includes forming a T-gate.

12. The method of claim 10, comprising:
electrically coupling the gate electrode with the third semiconductor material layer via a Schottky barrier material that is different from the fourth material.

13. The method of claim 12, wherein the Schottky barrier material includes titanium nitride.

14. The method of claim 10, wherein the fourth material includes tungsten.

15. The method of claim 10, wherein the second material and the third material include tungsten.

16. The method of claim 10, comprising:
electrically coupling the gate electrode with the Schottky barrier material via a connector, wherein the connector includes a material having a melting point above 500 degrees Celsius.

17. A method of forming a compound semiconductor heterostructure transistor device, the method comprising:
forming a first semiconductor material layer over a substrate, wherein the substrate includes a first material;
forming first and second portions of a second semiconductor material layer over the first semiconductor material layer;
forming a third semiconductor material layer over the first semiconductor material layer and between the first and second portions of the second semiconductor material layer so as to form a compound semiconductor heterostructure having a two-dimensional electron gas (2DEG) channel;
forming a drain electrode including a second material having a melting point above 500 degrees Celsius, and electrically coupling the drain electrode with the 2DEG channel via the first portion of the second semiconductor material layer;
forming a source electrode including a third material having a melting point above 500 degrees Celsius, and electrically coupling the source electrode with the 2DEG channel via the second portion of the second semiconductor material layer;
forming a gate electrode over the third semiconductor material layer, wherein the gate electrode includes a fourth material having a melting point above 500 degrees Celsius;
forming a Schottky barrier material including titanium nitride in contact with the third semiconductor material layer; and
annealing the Schottky barrier material at a temperature in the range of 400° C. to 500° C. to crystallize the titanium nitride.

18. The method of claim 17, wherein forming the gate electrode includes forming a T-gate.

19. The method of claim 17, comprising:
electrically coupling the gate electrode with the Schottky barrier material via a connector, wherein the connector includes a material having a melting point above 500 degrees Celsius.

20. The method of claim 19, wherein the fourth material includes tungsten.
